(19) United States
(12) Patent Application Publication
(10) Pub. No.: US 2012/0240982 A1
(43) Pub. Date: Sep. 27, 2012

(54) PHOTOVOLTAIC MODULE WITH INCREASED ACTIVE AREA

(75) Inventor: Jason Corneille, San Jose, CA (US)

(73) Assignee: MIASOLE, Santa Clara, CA (US)

(21) Appl. No.: 13/072,512

(22) Filed: Mar. 25, 2011

(51) Int. Cl. H01L 31/048

(52) U.S. Cl. 136/251

(57) ABSTRACT

A photovoltaic module according to the present invention comprises a transparent and flexible light-facing front layer, a non-light facing rear encapsulating layer, a plurality of interconnected photovoltaic cells disposed between the front layer and the back layer, a sealing compound, and wherein the transparent flexible front layer extends around and folds behind the back layer to form a seal behind the photovoltaic module, further wherein the seal comprises a sealing compound.

### BACKGROUND OF THE INVENTION

The invention is related generally to photovoltaic modules, and more specifically to sealing systems for improving the area utilization of light-facing surfaces of photovoltaic modules.

### BACKGROUND OF THE INVENTION

Photovoltaic cells are widely used for generation of electricity, where multiple photovoltaic cells are interconnected in module assemblies. Such modules may in turn be arranged in arrays, integrated into building structures or otherwise assembled to convert solar energy into electricity by the photovoltaic effect. Individual modules are encapsulated to protect the module components and photovoltaic cells from the environment. Current encapsulation techniques involve sealing photovoltaic cells between glass or polymer sheets to prevent moisture from contacting the photovoltaic cells. These sheets are generally sealed at their peripheral edges using opaque sealants that prevent light from reaching any photovoltaic cells in those areas, thereby reducing the total module area available for generating electricity. The area available for generating electricity is known as the “active area”.

There exists a need in the art to seal photovoltaic cells in a moisture resistant module without sacrificing any active area to the sealing region in order to maximize the electrical output and usable area.

### SUMMARY OF THE INVENTION

In one embodiment, a photovoltaic module housing interconnected photovoltaic cells is encapsulated with a flexible front sheet comprising a moisture resistant film or a moisture resistant multi-layer film, and comprises wrapping the light-facing flexible front sheet around the non-light-facing backsheet and forming a moisture resistant seal between the front sheet and back sheet in a region behind the photovoltaic cells.

In another embodiment, a photovoltaic module housing individual photovoltaic cells is encapsulated with a flexible front sheet comprising a moisture resistant film or a moisture resistant multi-layer film, and comprises wrapping the light-facing flexible front sheet around the photovoltaic cells and forming a moisture resistant seal between the front sheet and back sheet in a region behind the photovoltaic cells.

### BRIEF DESCRIPTION OF THE DRAWINGS

FIG. 1 is a schematic side cross-sectional view of a photovoltaic module in accordance with the prior art.

FIG. 2 is a schematic side cross-sectional view of a photovoltaic module with a flexible front layer according to one embodiment of the invention.

FIG. 3 is a schematic side cross-sectional view of a photovoltaic module with a flexible front layer according to another embodiment of the invention.

FIG. 4 is a schematic top view of a flexible front layer for a photovoltaic module with notched corner regions.

FIG. 5 is a schematic side cross-sectional view of a photovoltaic module with a flexible front layer and flexible back layer according to one embodiment of the invention.

### DESCRIPTION OF THE PREFERRED EMBODIMENTS

Reference will now be made in detail to specific embodiments of the invention. Examples of the specific embodiments are illustrated in the accompanying drawings. While the invention will be described in conjunction with these specific embodiments, it will be understood that it is not intended to limit the invention to such specific embodiments. On the contrary, it is intended to cover alternatives, modifications, and equivalents as may be included within the spirit and scope of the invention. In the following description, numerous specific details are set forth in order to provide a thorough understanding of the present invention. The present invention may be practiced without some or all of these specific details. In other instances, well known mechanical apparatuses and process operations have not been described in detail in order not to unnecessarily obscure the present invention.

Provided herein is a flexible, transparent encapsulating sheet incorporated into photovoltaic module configurations along with a sealing compound, wherein the sealing compound is opaque to light transmission, and the sealing region is arranged to substantially avoid blocking the light-facing or “active area” of a photovoltaic module. By placing the seal away from the active area of the photovoltaic cells, a moisture barrier can be created that can meet the minimum width requirement of the Underwriters Laboratories (UL) specification 1703 which calls for a minimum distance along any surface to the electrically active photovoltaic cells to be at least 1.3 cm. This specification, UL 1703, edition 3, as revised April 2008, is incorporated by reference herein in its entirety. By placing the moisture barrier behind the photovoltaic module, this requirement can be met while substantially avoiding blocking the light facing active area of the module. This in turn increases electrical output.

FIG. 1 depicts a cross-sectional view of a typical solar module of the prior art, 100, including interconnected solar cells 104 and front and back encapsulating layers 102 and 108, respectively. In this prior art example, the front and back encapsulating layers are rigid, generally comprised of panes of glass, and serve to protect the solar cells 104 and other module components from environmental conditions. In some embodiments, an encapsulating material 110 is employed to further protect and secure the photovoltaic cells within the module. Additionally, a sealing layer 106 is disposed at the perimeter of the encapsulating layers to provide a moisture resistant seal, which slows the rate of moisture ingress to the photovoltaic cells.

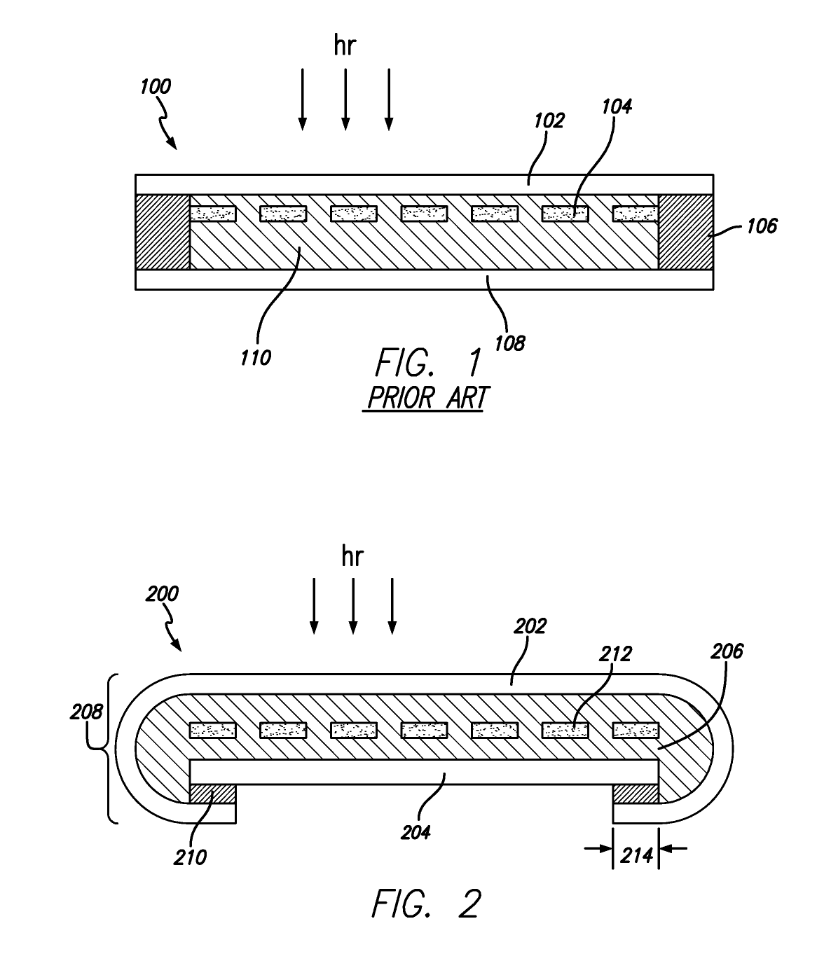

Embodiments of the present invention relate to encapsulating solar modules for environmental protection and mechanical support in order to maximize the light facing “active area.” FIG. 2 shows a cross-sectional view of a solar module 200, including interconnected photovoltaic cells 212 and front and back encapsulating layers 202 and 204, respectively. In this embodiment, a unique approach is taken wherein the front sheet is both transparent and flexible, and wraps around the back encapsulating layer 204 where it is sealed with moisture barrier layer 210 behind the module. Examples of flexible and transparent front layers 202 with sufficiently low water vapor transmission rates (WVTR) include 3M's Ultra Barrier Solar Film™, which has a WVTR of less than 5×10⁻⁴ g/m₂/day, and the flexible/transparent Barix™ films manufactured by Vitex Systems Inc. Generally, photovoltaic cells are known to degrade in the presence of moisture, and thus it is desirable to employ a encapsulating sheet having a reduced WVTR.

The structure in FIG. 2 includes sealing layer 210 located behind the module to avoid blocking the light facing surfaces of the photovoltaic cells with any opaque sealing compound. The photovoltaic cells may further be secured within a matrix of pottant material 206, such as ethylene vinyl acetate (EVA), a thermoplastic such as polyvinyl butyral (PVB), a thermoplastic ionomer resin such as DuPont Surlyn®, or other similar pottant materials as known in the art. In some embodiments, the pottant is between 25 microns and 500 microns, and in other embodiments is between 50 microns and 150 microns. The folded portion 208 of the flexible front encapsulating layer may optionally include a crease in front layer 202, and/or may comprise a smoothly curved region that does not include a crease, each of which allows the front layer to wrap around behind the back layer.

The sealing material may be comprised of a material with a low WVTR. In some embodiments the WVTR may be less than 10⁻² g/m²/day when measured at 38° C. and 100% relative humidity. In other embodiments the WVTR may be less than 10⁻³ g/m²/day when measured at 38° C. and 100% relative humidity. In still further embodiments the WVTR may be less than 10⁻⁴ g/m²/day when measured at 38° C. and 100% relative humidity. The sealing material may be comprised of various butyl rubber compounds containing, for example, a titanium zeolite desiccant to delay the onset of WVTR into the module.

In some embodiments, an anti-reflection coating is applied to the outer surface of the flexible transparent front layer. For example, a two-layer structure having a high refractive index layer with a thickness of 1 μm or less that is in contact with the flexible and transparent barrier layer, and a low refractive index layer deposited on the high refractive index layer may be used to reduce light reflection from the surface of the flexible layer, thereby increasing light transmission to the photovoltaic cells within a module. Alternatively, other anti-reflection coatings commonly known in the art may be applied, and in some embodiments may be used in combination with adhesion layers, anti-smudge layers, hard coating layers, or primer layers. In some embodiments, an anti-soiling layer, such the SOLARC™ coating manufactured by Honeywell, Inc., may be used in combination with an anti-reflection layer. In other embodiments, a hard coating layer is used without an anti-reflection layer. In other embodiments, a combination of hard coating and anti-soiling layers is used to improve the durability and ease of cleaning the photovoltaic module.

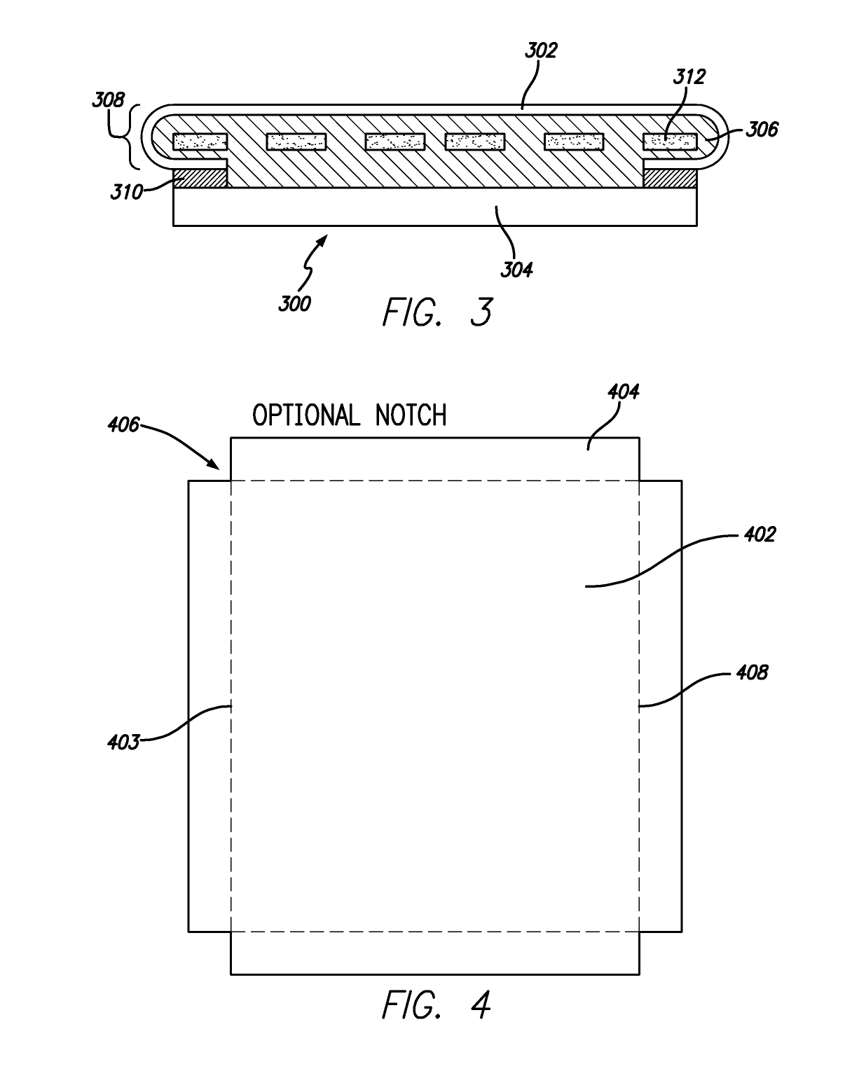

FIG. 3 shows a cross-sectional view of a solar module 300, including interconnected photovoltaic cells 312 and front and back encapsulating layers 302 and 304, respectively. In this embodiment, another novel approach is taken wherein the front sheet is both transparent and flexible, and is wrapped around behind photovoltaic cells 312. The module is sealed using sealing compound 310 located behind the light facing surface of the photovoltaic cells. This structure, wherein the sealing compound 310 is formed behind the photovoltaic cells, advantageously avoids blocking any of the light facing surface of the cells with the opaque sealing compound. In some embodiments, the photovoltaic cells are secured within a matrix of pottant material 306, such as ethylene vinyl acetate (EVA), or a thermoplastic such as polyvinyl butyral (PVB), a thermoplastic ionomer resin such as DuPont Surlyn®, or other pottant materials commonly known in the art. In some embodiments, the pottant is between 25 microns and 500 microns thick, and in other embodiments is between 50 microns and 150 microns thick. The folded portion 308 of the flexible front encapsulating layer optionally includes a crease (not shown) in the front layer 302, and/or comprises a smoothly curved region (as shown) without a crease that allows the front layer to wrap around behind the back layer.

FIG. 4 shows a top view of a flexible front layer in accordance with some embodiments of the invention. In this example, corner regions 406 have been cut, punched, or otherwise formed in the flexible front layer to improve the folding characteristics of the front layer over the rectangular shaped back layer. Shaded portion 402 depicts the area of an example back sheet (not shown), wherein the flexible front sheet is folded and/or curved along dotted lines 403. Flap areas 404 of the flexible front sheet are folded or curved behind the back layer (not shown) and the seal is formed behind the module as depicted in FIG. 3.

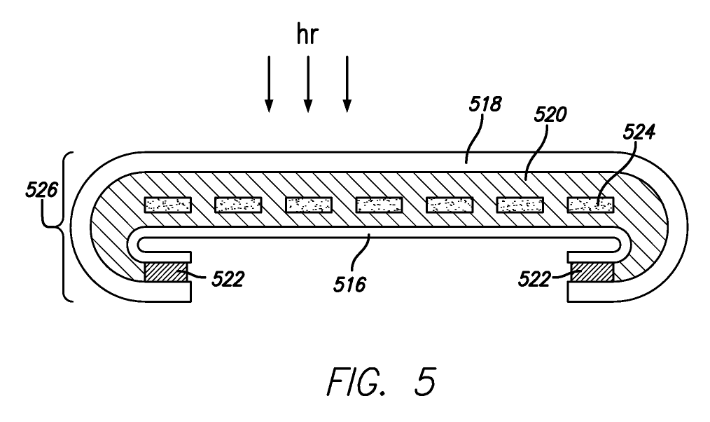

In another embodiment, the front layer is flexible and transparent and the back layer is also flexible, but not necessarily transparent, as shown in FIG. 5. In this example, both the transparent front layer 518 and the opaque back layer 516 are folded or curved behind the light facing surface of the photovoltaic cells 524, as shown. In some embodiments, the photovoltaic cells are secured within a matrix of pottant material 520, such as ethylene vinyl acetate (EVA), or a thermoplastic such as polyvinyl butyral (PVB), a thermoplastic ionomer resin such as DuPont Surlyn®, or other pottant materials commonly known in the art. In some embodiments, the pottant is between 50 microns and 500 microns thick, in other embodiments the pottant is between 75 microns and 250 microns thick. The folded portion 526 of the flexible encapsulating layers optionally includes a crease (not shown) in either or both of the layers, and/or comprises a smoothly curved region that does not include a crease. This allows the sealing compound 522 to form a moisture barrier between the front and back encapsulating layers without having any deleterious affect on the light facing area available to photovoltaic cells 524.

It is to be understood that the present invention is not limited to the embodiment(s) and the example(s) described above and illustrated herein, but encompasses any and all variations falling within the scope of the appended claims. For example, as is apparent from the claims and specification, not all method steps need be performed in the exact order illustrated or claimed, but rather in any order that allows the proper formation of the solar cells of the present invention.

What is claimed is:

1. A photovoltaic module comprising:
a flexible transparent front layer;
a back layer;
a plurality of interconnected photovoltaic cells disposed between the front layer and the back layer;
a sealing compound; and,
wherein the transparent flexible front layer extends around and folds behind the back layer to form a seal behind the photovoltaic module, further wherein the seal comprises a sealing compound.

2. The photovoltaic module of claim 1 wherein the transparent flexible front layer and the back layer have substantially coextensive end portions along a first direction.

3. The photovoltaic module of claim 1 wherein a coextensive front sheet end portion and a back sheet end portion together form an inwardly curved end portion, with said backsheet end portion on the interior of said inwardly curved end portion.

4. The photovoltaic module of claim 1, wherein the light facing area of the photovoltaic module receives light substantially unobstructed by the opaque sealing compound.

5. The photovoltaic module of claim 1 wherein,
the plurality of interconnected photovoltaic cells have a light incident top surface and a non-light incident back surface;
the transparent flexible front layer has overlapping first and second surfaces, the first surface facing in a direction opposite and away from the second surface;
the back layer has overlapping first and second surfaces, the first surface facing in a direction opposite and away from the second surface;
the first surface of the transparent flexible front layer faces away from the interconnected photovoltaic cells, and the second surface of the transparent flexible front layer faces towards the interconnected photovoltaic cells;
the first surface of the back layer faces toward the interconnected photovoltaic cells, and the second surface of the back layer faces in a direction opposite and away from the interconnected photovoltaic cells; and,
wherein the transparent flexible front layer extends around and folds behind the back layer and forms a seal, comprising the sealing compound, between the second surface of the transparent flexible front layer and the second surface of the back layer.

6. The photovoltaic module of claim 5 wherein the sealing compound extends at least 0.4 inches along the second surface of the transparent flexible front layer and the second surface of the back layer.

7. The photovoltaic module of claim 6 wherein the sealing compound comprises a titanium zeolite containing butyl rubber.

8. The photovoltaic module of claim 1 wherein the back layer is substantially rigid.

9. The photovoltaic module of claim 8 wherein the back layer comprises glass.

10. The photovoltaic module of claim 9 wherein the back layer has a thickness of greater than 4 mm.

11. The photovoltaic module of claim 1 wherein the transparent flexible front layer has a thickness of not more than 100 microns.

12. The photovoltaic module of claim 1 wherein the transparent flexible front layer has a water vapor transmission rate (WVTR) of less than 10−3 g/m²/day.

13. The photovoltaic module of claim 1 wherein the transparent flexible front layer comprises at least two layers and has a WVTR of less than 10E−4 g/m²/day.

14. The photovoltaic module of claim 5 wherein the transparent flexible front layer further comprises an anti-reflective coating layer on the outer light-facing surface.

15. The photovoltaic module of claim 5 wherein the transparent flexible front layer further comprises an anti-soiling layer on the outer light-facing surface.

16. The photovoltaic module of claim 1 wherein the transparent flexible front layer is selected from at least one of the group consisting of polyethylene terepthalate (PET), nylons, acrylonitrile butadiene styrene (ABS), polybutylene terephtalate (PBT), polycarbonate (PC), polyphenylene sulfide (PPS), and polyphenylene oxide (PPO).

17. A photovoltaic module comprising:
a transparent flexible front layer;
a back layer;
a plurality of interconnected photovoltaic cells disposed between the transparent flexible front layer and the back layer;
a sealing compound; and,
wherein the transparent flexible front layer extends around and folds behind the photovoltaic cells to form a seal behind the photovoltaic cells and between transparent flexible front layer and the back layer.

18. The photovoltaic module of claim 17 wherein the transparent flexible front layer and the back layer have substantially coextensive end portions along a first direction.

19. The photovoltaic module of claim 17, wherein the light facing area of the photovoltaic module receives light substantially unobstructed by the opaque sealing compound.

20. The photovoltaic module of claim 17 wherein,
the plurality of interconnected photovoltaic cells have a light incident top surface and a non-light incident back surface;
the transparent flexible front layer has overlapping first and second surfaces, the first surface facing in a direction opposite and away from the second surface;
the back layer has overlapping first and second surfaces, the first surface facing in a direction opposite and away from the second surface;
the first surface of the transparent flexible front layer faces away from the interconnected photovoltaic cells, and the second surface of the transparent flexible front layer faces towards the interconnected photovoltaic cells;
the first surface of the back layer faces toward the interconnected photovoltaic cells, and the second surface of the back layer faces in a direction opposite and away from the interconnected photovoltaic cells; and,
wherein the transparent flexible front layer extends around and folds behind the back layer and forms a seal, comprising the sealing compound, between the second surface of the transparent flexible front layer and the second surface of the back layer.

21. The photovoltaic module of claim 20 wherein the sealing compound extends at least 0.4 inches along the second surface of the transparent flexible front layer and the second surface of the back layer.

22. The photovoltaic module of claim 21 wherein the sealing compound comprises a titanium zeolite containing butyl rubber.

23. The photovoltaic module of claim 17 wherein the back layer is substantially rigid.

24. The photovoltaic module of claim 23 wherein the back layer comprises glass.

25. The photovoltaic module of claim 24 wherein the back layer has a thickness of greater than 4 mm.

26. The photovoltaic module of claim 17 wherein the transparent flexible front layer has a thickness of no more than 100 microns.

27. The photovoltaic module of claim 17 wherein the transparent flexible front layer has a water vapor transmission rate (WVTR) of less than 10−3 g/m²/day.

28. The photovoltaic module of claim 17 wherein the transparent flexible front layer comprises at least two layers and has a WVTR of less than 10E−4 g/m²/day.

29. The photovoltaic module of claim 20 wherein the transparent flexible front layer further comprises an anti-reflective coating layer.

30. The photovoltaic module of claim 20 wherein the transparent flexible front layer further comprises an anti-soiling layer on the outer light-facing surface.

31. The photovoltaic module of claim 17 wherein a coextensive front sheet end portion and a back sheet end portion together form an inwardly curved end portion, with said backsheet end portion on the interior of said inwardly curved end portion.

32. A photovoltaic module comprising:
a transparent flexible front layer;
a flexible back layer;
a plurality of interconnected photovoltaic cells disposed between the transparent flexible front layer and the back layer;
a sealing compound;
the transparent flexible front layer and the flexible back layer having substantially coextensive end portions along a first direction; and,
wherein the front sheet and the back sheet together form an inwardly curved end portion, with said backsheet end portion on the interior of said inwardly curved end portion.
